(19) United States
(12) Patent Application Publication
(10) Pub. No.: US 2010/0134195 A1
(43) Pub. Date: Jun. 3, 2010

(54) CAPACITOR HAVING VARIABLE CAPACITANCE AND DIGITALLY CONTROLLED OSCILLATOR INCLUDING THE SAME

(75) Inventors: Ja Yol LEE, Daejeon (KR); Byung Hun Min, Gunsan (KR); Seong Do Kim, Daejeon (KR); Hyun Kyu Yu, Daejeon (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/629,742

(22) Filed: Dec. 2, 2009

(30) Foreign Application Priority Data
Dec. 3, 2008 (KR) 10-2008-0121851
Jun. 22, 2009 (KR) 10-2009-0055584

(51) Int. Cl. H03B 5/12; H01L 27/06

(52) U.S. Cl. 331/117 FE; 257/306; 257/E27.016

(57) ABSTRACT

There is provided a capacitor having variable capacitance, which forms different capacitances according to a control signal by applying a switch to a metal-oxide-metal (MOM) structure plate capacitor using a CMOS process. The capacitor includes a stack structure including a plurality of metal layers including a first metal layer, and a plurality of dielectric layers respectively interposed between the plurality of metal layers, and a switch part including at least one switch having one side connected to at least one metal layer among the plurality of metal layers other than the first metal layer. The first metal layer and the other side of the switch serve as both terminals of the capacitor, and at least two capacitances are provided between both terminals of the capacitor upon controlling a short/open of the switch.

### CROSS-REFERENCE TO RELATED APPLICATIONS

This application claims the priority of Korean Patent Application Nos. 10-2008-0121851 filed on Dec. 3, 2008 and 10-2009-0055584 filed on Jun. 22, 2009, in the Korean Intellectual Property Office, the disclosures of which are incorporated herein by reference.

### BACKGROUND OF THE INVENTION

1. Field of the Invention

The present invention relates to a capacitor having variable capacitance and a digital controlled oscillator including the same, and more particularly, to a capacitor having variable capacitance, which forms a different capacitance according to a control signal by applying a switch to a plate capacitor having a metal-oxide-metal (MOM) structure, and a digitally controlled oscillator including the same.

2. Description of the Related Art

In general, a phase-locked loop (PLL) circuit employing a charge pump has been commonly used in designing a radio frequency (RF) synthesizer for multi-band mobile communications. An analog circuit design technology has been integrated into a PLL circuit employing a charge pump.

It is difficult to integrate such a PLL circuit together with a digital baseband signal processing block using a digital complementary metal oxide semiconductor (CMOS) process, since an additional analog/RF library is required in addition to a design library, provided in a standard digital CMOS process, due to analog circuits and analog signal characteristics.

Furthermore, the recent development in process technologies has led to the development of a nanoscale digital CMOS process. Thus, a digital baseband signal processing block is under development using this nanoscale digital CMOS process.

In response to the development of nanotechnologies, a digital circuit may be easily adapted to a process technique which is to be realized, without being redesigned, whereas an analog/RF circuit needs to be redesigned undesirably whenever the process technique is changed.

The nanoscale CMOS process causes a reduction in operating voltage, and is thus rendered unsuitable for an analog/RF circuit.

Solving limitations caused in designing an analog/RF integrated circuit using the nanoscale digital CMOS process is both time-consuming and costly. Therefore, studies are actively ongoing to develop digital RF technologies allowing for the digital implementation of an analog/RF circuit block.

In particular, a frequency synthesizer of an RF transceiver is known to be a device that can be realized as a fully digital device. A digital PLL frequency synthesizer technology has long been studied. However, due to poor phase noise and jitter characteristics, this digital PLL frequency synthesizer has almost not been used as the local oscillator of an RF transceiver for mobile communications requiring high-quality phase noise.

However, All Digital PLL (ADPLL) circuits have been newly developed by applying the digital PLL technology to a frequency synthesizer for mobile communications.

The difference between the related art digital PLL circuit and this ADPLL circuit is in a digitally controlled oscillator (DCO). A DCO implemented using a digital logic is employed according to the related art; however, a technique implemented using an LC resonator has recently been used.

The DCO implemented using an LC resonator is advantageous over the DCO using a digital logic in terms of phase noise and jitter noise.

However, the DCO employing an LC resonator has a lower frequency resolution as compared with a typical voltage controlled oscillator, since it adjusts an oscillation frequency by tuning the fine capacitance variation of the LC resonator.

Since the frequency resolution of the DCO employing an LC resonator is directly proportional to the resolution of capacitance (i.e., unit variation in capacitance), studies are actively ongoing in order to improve the resolution of capacitance.

### SUMMARY OF THE INVENTION

An aspect of the present invention provides a capacitor having variable capacitance, which can achieve a significant reduction in a capacitance variation so as to render the capacitor applicable to a digitally controlled oscillator (DOC) employing an LC resonator having a high frequency resolution.

An aspect of the present invention also provides a DCO including the capacitor having variable capacitance.

According to an aspect of the present invention, there is provided a capacitor having variable capacitance, including: a stack structure including a plurality of metal layers including a first metal layer, and a plurality of dielectric layers respectively interposed between the plurality of metal layers; and a switch part including at least one switch having one side connected to at least one metal layer among the plurality of metal layers other than the first metal layer. The first metal layer and the other side of the switch serve as both terminals of the capacitor, and at least two capacitances are provided between both terminals of the capacitor upon controlling a short/open of the switch.

The dielectric layers may be formed of an oxide. The stack structure may be formed by using a complementary metal oxide semiconductor (CMOS) process.

The stack structure may include the first metal layer, a second metal layer facing the first metal layer with the dielectric layer therebetween, and a third metal layer facing the first metal layer with the dielectric layer therebetween, the second metal layer and the third metal layer each being spaced apart from the first metal layer at a different interval by the dielectric layer. The switch part may include a first switch formed between the first metal layer and the second metal layer, and a second switch formed between the first metal layer and the third metal layer. The first switch maybe an N-channel MOS transistor including a drain connected to one terminal of the capacitor and a source connected to the second metal layer. The second switch may be a P-channel MOS transistor including a source connected to the one terminal of the capacitor and a drain connected to the third metal layer. A common control signal may be input to respective gates of the N-channel MOS transistor and the P-channel MOS transistor.

The stack structure may include the first metal layer, a second metal layer facing the first metal layer with the dielectric layer therebetween, and a third metal layer facing the first metal layer with the dielectric layer therebetween, the second metal layer and the third metal layer each being spaced apart from the first metal layer at a different interval by the dielectric layer. The switch part may include a first inverter having an input terminal to which a control signal is input, and an output terminal connected to the third metal layer, and a second inverter having an input terminal connected to the output terminal of the first inverter and an output terminal connected to the second metal layer.

The first metal layer may be disposed between the second metal layer and the third metal layer, and the first to third metal layers may have substantially the same surface area.

The plurality of metal layers may each have a different surface area, and the first metal layer of the plurality of metal layers may have the largest surface area. The first metal layer and each of the other metal layers may be disposed to have a region in which the first metal layer and each of the other metal layers face each other through the dielectric layer.

The first metal layer of the stack structure may be formed on almost the entire surface of one layer, and the other metal layers of the stack structure may each have a plurality of parts separated on the same layer. The switch part may be connected between one terminal of the capacitor and each part of the other metal layers. A capacitance may be formed selectively between the first metal layer and the parts of the other metal layers upon controlling a short/open of the switch.

According to another aspect of the present invention, there is provided a digitally controlled oscillator including: a capacitor unit including a capacitor having variable capacitance; an inductor connected in parallel to the capacitor part; and a cross-coupled pair connected to the capacitor unit and the inductor and generating negative resistance. Here, the capacitor may include a stack structure including a plurality of metal layers including a first metal layer, and a plurality of dielectric layers respectively interposed between the plurality of metal layers, and a switch part including at least one switch having one side connected to at least one metal layer among the plurality of metal layers other than the first metal layer, wherein the first metal layer and the other side of the switch serve as both terminals of the capacitor, and at least two capacitances are provided between both terminals of the capacitor upon controlling a short/open of the switch

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are cross-sectional views illustrating a capacitor having variable capacitance according to an exemplary embodiment of the present invention;

FIGS. 2A and 2B are equivalent circuit diagrams illustrating a capacitance formed by a switching operation of the capacitor of FIGS. 1A and 1B;

FIGS. 3A and 3B illustrate a switch part of FIGS. 1A and 1B, according to an exemplary embodiment of the present invention;

FIGS. 4A and 4B illustrate a switch part of FIGS. 1A and 1B, according to another exemplary embodiment of the present invention;

FIGS. 5A and 5B are cross-sectional views illustrating a capacitor having a variable capacitor according to another exemplary embodiment of the present invention;

FIG. 6 is a cross-sectional view illustrating a stack structure of a capacitor having variable capacitance according to another exemplary embodiment of the present invention.

FIGS. 7A through 7C are plan views illustrating a metal-layer structure within the stack structure of the capacitor of FIG. 6;

FIG. 8 is a cross-sectional view illustrating a capacitor adopting the stack structure of FIG. 6; and

FIG. 9 is a circuit diagram showing one example of a digitally controlled oscillator (DCO) to which a capacitor having variable capacitance, according to the present invention, is applicable.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions of elements are exaggerated for clarity.

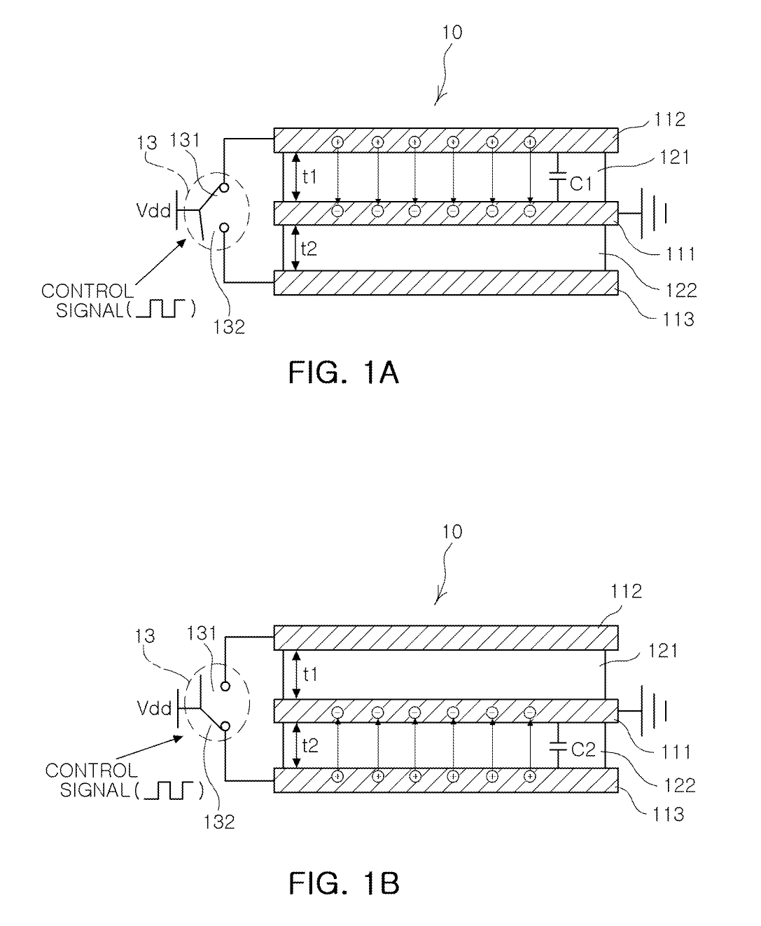

FIGS. 1A and 1B are cross-sectional views illustrating a capacitor having variable capacitance according to an exemplary embodiment of the present invention.

As shown in FIGS. 1A and 1B, a capacitor, according to this embodiment of the present invention, includes a stack structure 10 of a plurality of metal layers 111 to 113 and dielectric layers 121 and 122, and a switch part 13.

The stack structure 10 has a metal-oxide-metal (MOM) structure including the three metal layers 111 to 113, and the two dielectric layers 121 and 122. These three metal layers 111 to 113 may include a first metal layer 111, and second and third metal layers 112 and 113 each opposing the first metal layer 111. Here, the second and the third metal layers 112 and 113 are each spaced apart from the first metal layer 111 at a different interval because of the dielectric layers 121 and 122 respectively disposed between the second metal layer 112 and the first metal layer 111 and between the third metal layer 113 and the first metal layer 111. In detail, the first metal layer 111 may be disposed between the second metal layer 112 and the third metal layer 113, and the first to third metal layers 111 and 113 may have substantially the same surface area.

The switch part 13 may be implemented using a relay switch, or using switches, that is, a first switch 131 connecting one terminal (a terminal to which power voltage Vdd is applied in FIG. 1) of a capacitor with the second metal layer 112 and a second switch 132 connecting the one terminal of the capacitor with the third metal layer 113. The switch part 13 may selectively connect the second metal layer 112 or the third metal layer 113 with an output terminal of the capacitor according to the state of a control signal. That is, the switch part 13 may have opposite operational states according to a control signal.

The capacitor depicted in FIGS. 1A and 1B is illustrated as having both terminals connected between power voltage Vdd and the ground. One side of the switch part 13, connected to the power voltage Vdd, may serve as one terminal of the capacitor, and the first metal layer 111 may serve as the other terminal of the capacitor.

The operation method of the capacitor, according to an exemplary embodiment of the present invention, will now be described in more detail.

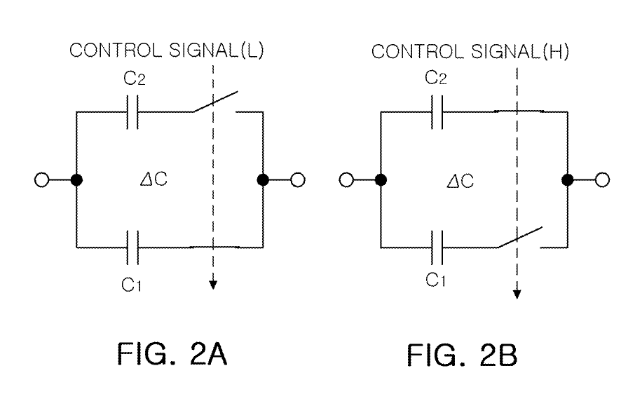

As shown in FIG. 1A, when the first switch 131 is shorted and the second switch 132 is opened, the first metal layer 111 and the second metal layer 112 are connected to the ground plane and the power voltage Vdd, respectively. Thus, an electric field is induced between the first metal layer 111 and the second metal layer 112 to thereby form a capacitance C1, and an equivalent circuit as depicted in FIG. 2A is obtained.

In contrast, as shown in FIG. 1B, when the first switch 131 is opened and the second switch 132 is shorted, the first metal layer 111 and the third metal layer 113 are connected to the ground plane and the power voltage Vdd, respectively. Then, an electric field is induced between the first metal layer 111 and the third metal layer 113 to thereby form a capacitance C2, and an equivalent circuit as depicted in FIG. 2B is obtained.

As described above, the capacitor, according to this embodiment, varies a capacitance, formed in the stack structure 10, by changing the operational states of the first switch 131 and the second switch 132. In this way, a fine capacitance variation (ΔC=C1−C2) may be created.

A capacitance may be tuned more finely by using this fine capacitance variation of the capacitor of this embodiment, instead of a unit capacitance applied to a fine-tuned bank to be described later with reference to FIG. 9.

For example, in the event that a unit capacitor is directly created, it is technically impossible to form a very small capacitance due to limitations in processes and the like. In contrast, according to this embodiment of the present invention, the capacitor uses the capacitance variation created through a switching operation, and thus may realize a capacitance having a very small value only by setting a difference value between two capacitances (i.e., the capacitance variation) to be small.

If a fine-tuned bank, as depicted in FIG. 9, employs the capacitor of this embodiment, capacitance may be more finely tuned to thereby enhance the operational precision.

The stack structure 10 of this embodiment having an MOM capacitor structure, a conductor plate capacitor, has a capacitance as expressed by Equation 1 below:

$$C = ɛ \frac{S}{t} \qquad Equation 1$$

where S denotes the surface area of a conductor, t denotes a thickness of a dielectric body, and ε denotes a dielectric constant of the dielectric body and may be represented by the multiplication of εᵣ by ε₀. Here, εᵣ denotes a relative dielectric constant, and ε₀ is 8.85*10⁻¹² [F/m].

According to Equation 1 above, the stack structure 10 of this embodiment generates a capacitance that is proportional to the surface area of the conductor plate and the dielectric constant of the dielectric body, and inversely proportional to the thickness of the dielectric body. That is, the stack structure 10 of this embodiment may generate capacitances having various values by using the surface area of the conductor plate, the dielectric constant or the thickness of the dielectric body (hereinafter, also referred to as dielectric thickness).

In FIG. 1, a capacitance variation is created by using an interval difference between an interval between the first metal layer 111 and the second metal layer and an interval between the first metal layer 111 and the third metal layer 113. As illustrated in the equivalent circuit of FIG. 2, the first and second switches 131 and 132 operate in opposite states so that a capacitance C1 is generated when a digital control signal is logic low, and a capacitance C2 is generated when a digital control signal is logic high. In this case, a fine capacitance variation may be obtained by the state transition of the digital control signal.

The two capacitances generated by the switching as illustrated in FIG. 1 are expressed by Equations 2 and 3 below, and a fine capacitance variation ΔC, obtained by these two capacitances, may be expressed by Equation 4 below:

$$\begin{matrix}C 1 = ɛ \frac{S}{t 1} & Equation 2 \\ C 2 = ɛ \frac{S}{t 2} & Equation 3 \\ Δ C = C 1 - C 2 = ɛ S ( \frac{1}{t 1} - \frac{1}{t 2} ) = ɛ S ( \frac{t 2 - t 1}{t 1 t 2} ) & Equation 4\end{matrix}$$

As shown in Equation 4 above, a fine capacitance variation ΔC, which may be formed by the capacitor structure depicted in FIG. 1, becomes smaller as the surface area of the metal layer, the dielectric constant, and the thickness difference between the dielectric layers are reduced.

That is, the frequency resolution of a DCO may be increased by reducing at least one of the surface area of the metal layer, the dielectric constant and the thickness difference between the dielectric layers.

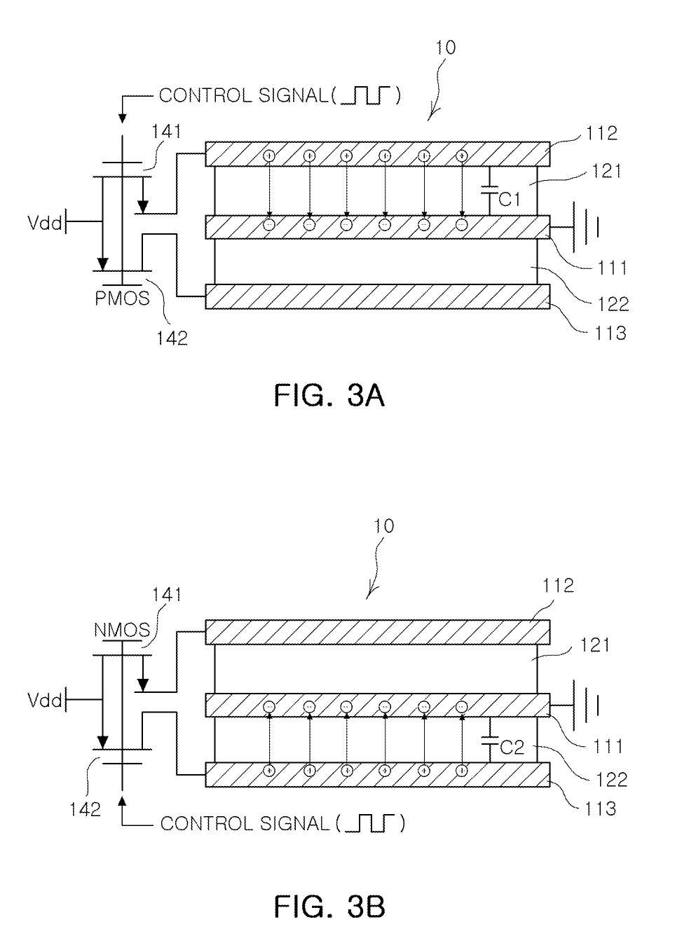

FIGS. 3A and 3B illustrate the switch part of FIG. 1, according to an exemplary embodiment of the present invention. The switches depicted in FIGS. 3A and 3B are implemented using MOS transistors.

As shown in FIGS. 3A and 3B, the switch part of the capacitor, according to this embodiment of the invention, may include a first switch 141 connecting the second metal layer 112 with one terminal of a capacitor, and a second switch 142 connecting the third metal layer 113 with the one terminal of the capacitor.

The first switch 141 is an N-channel MOS transistor having a drain connected to one terminal of the capacitor, (i.e., a terminal receiving power voltage Vdd of FIG. 2), and a source connected to the second metal layer 112. The second switch 142 is a P-channel MOS transistor having a source connected to the one terminal of the capacitor, and a drain connected to the third metal layer 113. A control signal may be input in common to respective gates of the N-channel MOS transistor 141 and the P-channel MOS transistor 142.

The two first and second switches 141 and 142, configured in the above manner, have opposing states of short-circuit and open-circuit states according to the state of a control signal. Thus, a capacitance variation ΔC, corresponding to the difference between two capacitances C1 and C2, may be obtained by using a single control signal.

As shown in FIG. 3A, when a control signal input to the gate of each transistor is logic high, the N-channel MOS transistor 141 is turned ON and therefore, a capacitance C2 is formed by the first metal layer 111 and the second metal layer 112. In contrast, as shown in FIG. 3B, when a control signal is logic low, the P-channel MOS transistor 142 is turned ON and therefore, a capacitance C2 is formed by the first metal layer 111 and the third metal layer 113.

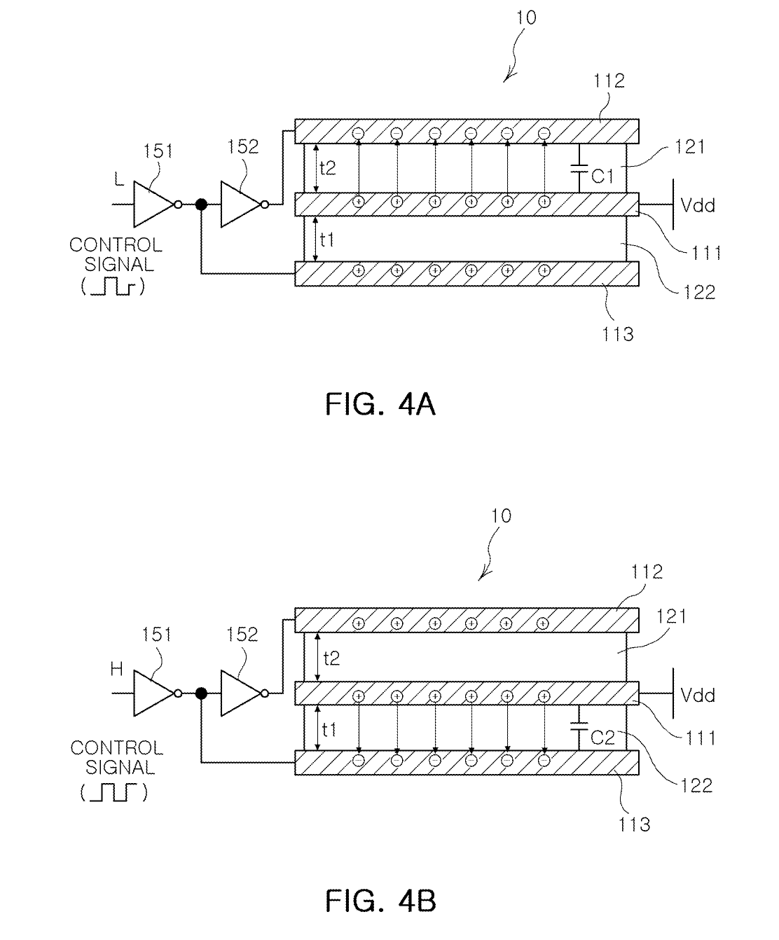

FIGS. 4A and 4B illustrate the switch part of FIG. 1, according to another exemplary embodiment of the present invention. The switches depicted in FIGS. 4A and 4B are implemented using inverters.

As shown in FIGS. 4A and 4B, the switch part of the capacitor, according to another exemplary embodiment of the present invention, may include a first inverter 151 having an input terminal receiving a control signal, and an output terminal connected to the third metal layer 113, and a second inverter 152 having an input terminal connected to the output terminal of the first inverter 151 and an output terminal connected to the second metal layer 112.

Such a configuration of the switch part may also contribute to causing the second metal layer 112 and the third metal layer 113 to have opposite potentials, using a single control signal. Accordingly, a capacitance variation ΔC, corresponding to the difference between two capacitances C1 and C2 may be implemented by using a single control signal.

Unlike the illustration of FIGS. 1A and 1B and 3A and 3B, the first metal layer 111 of FIGS. 4A and 4B is connected to power voltage Vdd. However, even if the first metal layer 111 is connected to the ground plane in this embodiment, it is obvious to those skilled in the art that the basic operational principle is the same.

As shown in FIG. 4A, when a logic low control signal is input to the switch part, a logic low signal is applied to the second metal layer 112 via the first and second inverters 151 and 152 to thereby form negative charges. This creates an electric field between the second metal layer 112 and the first metal layer 111 connected to the power voltage Vdd, and a capacitance C1 is formed accordingly. In this case, however, a logic high signal is applied to the third metal layer 113 via the first inverter 151, and thus, the first metal layer 111 and the third metal layer 113 are at the same potential, thereby making an electric field disappear.

In the same way, as shown in FIG. 4B, when a logic high control signal is input to the switch part, a logic low signal is applied to the third metal layer 113 via the first inverter 151 to thereby form negative charges. This creates an electric field between the third metal layer 113 and the first metal layer 111 connected to the power voltage Vdd, and a capacitance C2 is formed accordingly. However, in this case, a logic high signal is applied to the second metal layer 112 via the first and second inverters 151 and 152, and thus the second metal layer and the first metal layer 111 are at the same potential, thereby making an electric field disappear.

As described above, in the embodiments depicted in FIGS. 3A and 3B and FIGS. 4A and 4B, when a control signal is transited from a high level (logic high) to a low level (logic low) and vice versa, a capacitance variation AC is created.

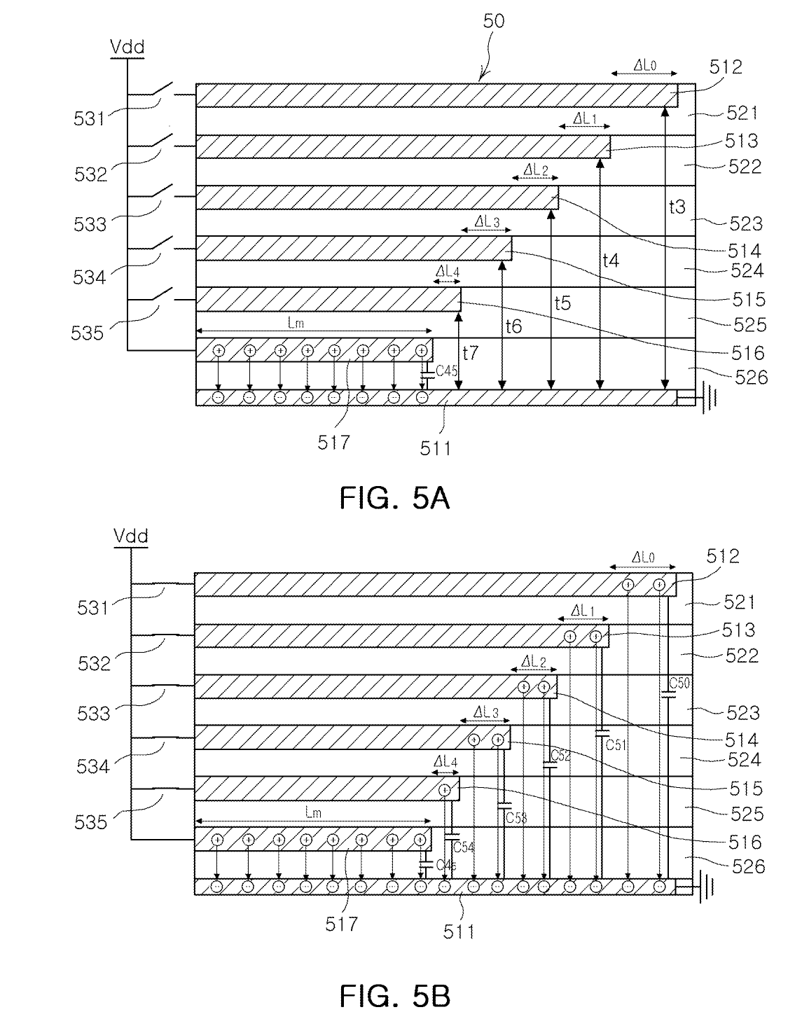

FIGS. 5A and 5B are cross-sectional views illustrating a capacitor having variable capacitance, according to another exemplary embodiment of the present invention.

Referring to FIGS. 5A and 5B, the capacitor having variable capacitance, according to another exemplary embodiment of the invention, may include a stack structure 50 of a plurality of metal layers 511 to 517 each having a different surface area, and a switch part 53 including a plurality of switches 531 to 535 having one set of ends respectively connected to the metal layers 512 to 516 among the plurality of metal layers 511 to 517.

Referring to FIGS. 5A and 5B, a first metal layer 511 among the plurality of metal layers 511 to 517 is used as one terminal of a capacitor and connected to the ground, and the other set of ends of the switches 531 to 535 are used as the other terminal of the capacitor and connected to power voltage Vdd.

A metal layer 517 among the plurality of metal layers 511 to 517 may be connected directly to the other terminal of the capacitor (i.e., the terminal to which power voltage Vdd is applied) without using a switch.

As shown in FIGS. 5A and 5B, the plurality of metal layers 511 to 517 may have the same width but be of different lengths. The first metal layer 511 may be disposed as the lowermost metal layer, and the remainder of the metal layers may be disposed in the upper regions as they have greater lengths.

The metal layers 512 to 517, other than the first metal layer 511, directly face the first metal layer 511 through dielectric layers at respective lengths ΔL0 to ΔL4 (hereinafter, ‘offset lengths’), without overlapping one another. The offset lengths may determine capacitances C50 to C54 formed between the first metal layer 511 and other metal layers 512 and 517, respectively.

The capacitor depicted in FIGS. 5A and 5B may implement variable capacitance by adding the capacitance between the first metal layer 511 and each of the offset length regions of the other metal layers 512 to 517 to the capacitance formed between the first metal layer 511 and the metal layer 517.

In the capacitor depicted in FIGS. 5A and 5B, the stack structure 50 of an MOM capacitor may be manufactured by using a complementary metal oxide semiconductor (CMOS) process including a seven metal layer process and a six oxide layer process. In FIGS. 5A and 5B, oxide layers are inserted between the metal layers 511 to 517 as a dielectric body. The metal layers 512 to 517, other than the first metal layer 511, may have the same length but have different lengths by their respective offset lengths ΔL0 to ΔL4.

As in the example depicted in FIGS. 5A and 5B, the length of the metal layer 516 may be longer than the length Lₘ of the metal layer 517 by the offset length ΔL4, the length of the metal layer 515 may be longer than the length of the metal layer 516 by the offset length ΔL3, the length of the metal layer 514 may be longer than that of the metal layer 515 by the offset length ΔL2, and the length of the metal layer 513 may be longer than that of the metal layer 514 by the offset length ΔL1, and the length of the metal layer 512 may be longer than that of the metal layer 513 by the offset length ΔL0. The offset length of each of the metal layers may be used to tune the capacitance between the first metal layer 511 and the corresponding metal layer of the metal layers 512 to 517 formed above the first metal layer 511.

The oxide dielectric formed between the first metal layer 511 and the remainder of the metal layers increases in thickness toward the uppermost metal layer. Thus, capacitances formed between the first metal layer 511 and the respective offset-length portions of the other metal layers decrease in magnitude toward the uppermost metal layer.

As described above, in the embodiment of FIGS. 5A and 5B, different capacitances are formed due to the offset lengths of the metal layers 512 to 517 other than the first metal layer 511, and the different dielectric thickness between each offset-length portion and the first metal layer 511.

As shown in FIGS. 5A and 5B, the metal layers 512 to 517, formed above the first metal layer 511, are connected to the power voltage Vdd via the switches 531 to 535. Each of the switches 531 to 535 is shorted or opened according to a digital control signal. The metal layer 517 may be connected directly to the power voltage Vdd and the first metal layer 511 may be grounded.

In FIG. 5A, the metal layer 517 is positively charged by the power voltage Vdd, so that an electric field is formed between the metal layer 517 and the first metal layer 511 connected to the ground to thereby maintain a constant capacitance.

In FIG. 5B, when all the switches 531 to 535 are turned ON by a digital control signal, the portions corresponding to the offset lengths ΔL0 to ΔL4 of the upper metal layers 512 to 516 (hereinafter, offset-length portions) are positively charged. This forms an electric field between the first metal layer 511 and each of the metal layers 512 to 517, thereby forming capacitances C50 to C54.

For example, assuming that a common width of each metal layer is defined as W, the surface area of the metal layer 512 corresponding to its offset length ΔL0 is W·ΔL0. Therefore, the capacitance C50 formed between the first metal layer 511 and the metal layer 512 may be determined by Equation 5 below.

Likewise, the surface area of the metal layer 513 corresponding to its offset length ΔL1 is W·ΔL1, and the capacitance C51 between the first metal layer 511 and the metal layer 513 may be determined by Equation 6 below. Also, a capacitance variation ΔC between these two capacitances C50 and C51 may be determined by Equation 7 below:

$$\begin{matrix}C 50 = ɛ \frac{S}{t 3} = ɛ \frac{W \cdot Δ L 0}{t 3} & Equation 5 \\ C 51 = ɛ \frac{S}{14} = ɛ \frac{W \cdot Δ L 1}{t 4} & Equation 6 \\ Δ C = C 50 - C 51 = ɛ W ( \frac{Δ L 0}{t 3} - \frac{Δ L 1}{t 4} ) & Equation 7\end{matrix}$$

Based on Equation 7, the offset length may be adjusted in order to maintain the constant capacitance variation ΔC between adjacent metal layers, each forming a capacitance with the first metal layer 511.

As for a DCO depicted in FIG. 9, when a switch is turned ON in a fine-tuned capacitor bank 92, a capacitance needs to increase to a unit capacitance. For this reason, to apply the capacitor of FIG. 5 to the fine-tuned capacitor bank 92 of the DCO of FIG. 9, the capacitance difference (i.e., capacitance variation) between adjacent metal layers each forming its own capacitance with the first metal layer 511 needs to be maintained at a constant level and have the same value (i.e., magnitude) as that of the unit capacitance. This principle is expressed by Equation 8 below:

$$\begin{matrix}Δ C = C 50 - C 51 \\ = ɛ W ( \frac{Δ L 0}{t 3} - \frac{Δ L 1}{t 4} ) \\ = C 51 - C 52 \\ = ɛ W ( \frac{Δ L 1}{t 4} - \frac{Δ L 2}{t 5} ) \\ = C 52 - C 53 \\ = ɛ W ( \frac{Δ L 2}{t 5} - \frac{Δ L 3}{6} ) \\ = C 53 - C 54 \\ = ɛ W ( \frac{Δ L 3}{t 6} - \frac{Δ L 4}{t 7} ) \\ = C 54 \\ = ɛ W \frac{Δ L 4}{t 7}\end{matrix} \qquad Equation 8$$

As shown in Equation 8 above, ΔC representing a base monotone increment of a capacitance is equal to the capacitance C54 formed between the metal layer 516 and the first metal layer 511. The respective offset lengths of the metal layers 512 to 515 maybe adjusted in order to cause the capacitance difference between adjacent metal layers, each forming a capacitance with the first metal layer 511, to be equal to the capacitance C54.

That is, the capacitor of FIG. 5, according to another exemplary embodiment of the present invention, may tune the overall capacitance by using the capacitance C54 as a unit capacitance according to a digital control signal.

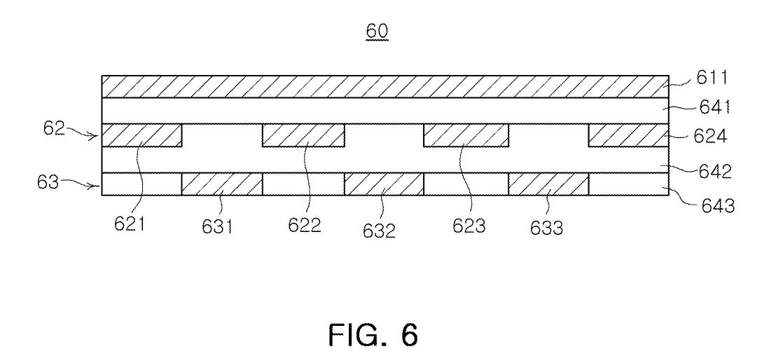

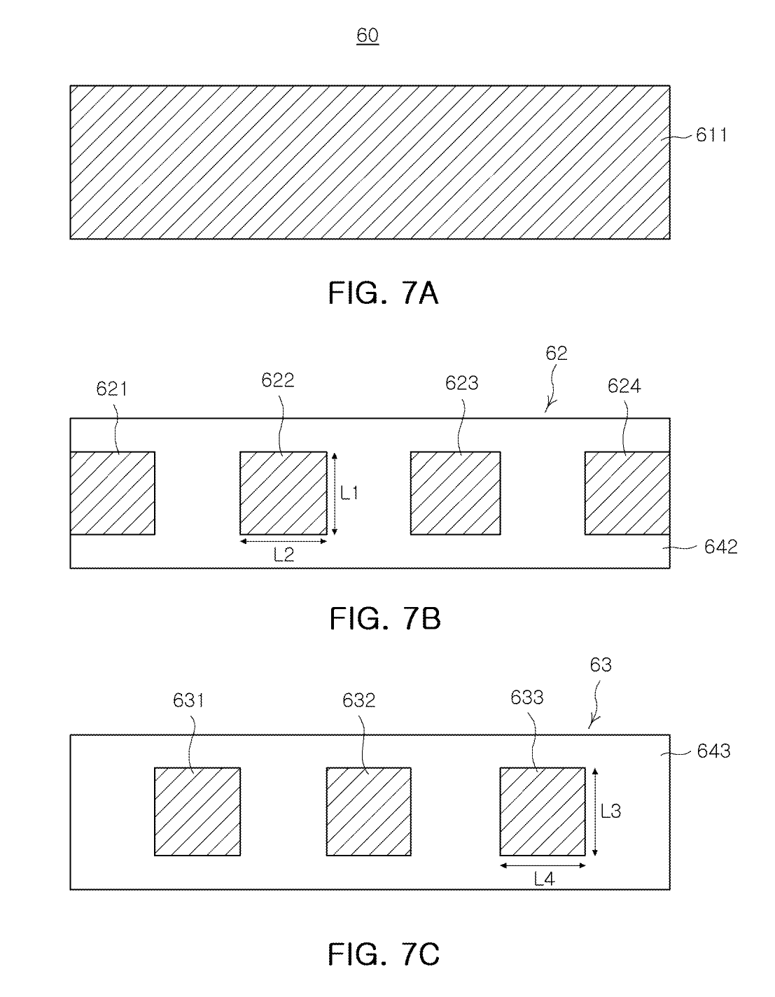

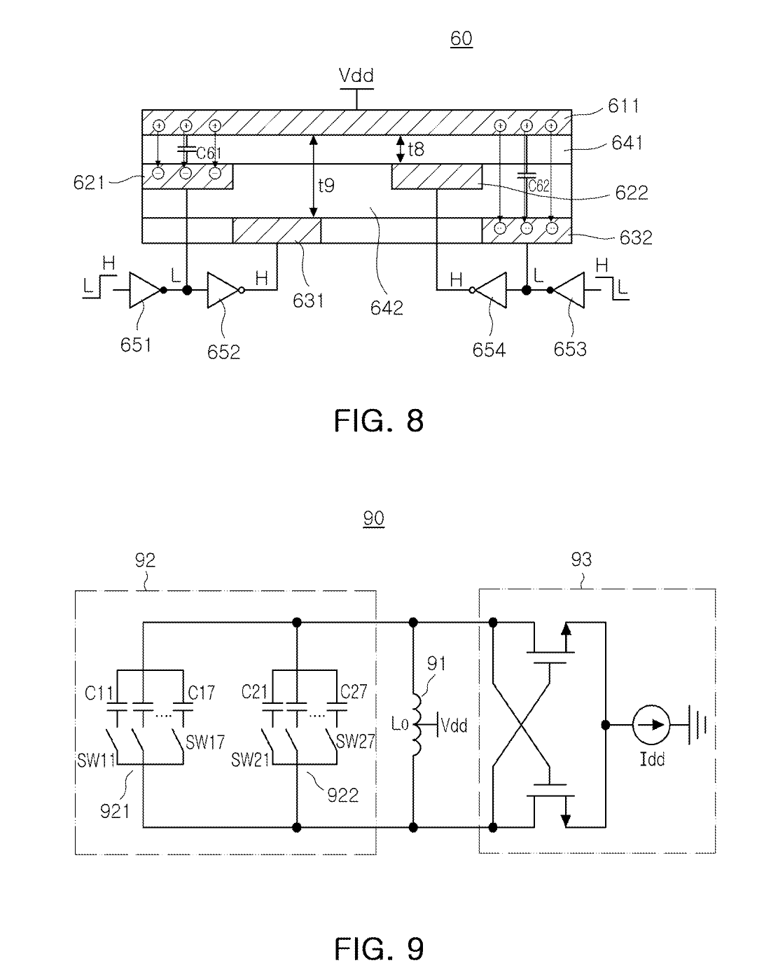

FIG. 6 is a cross-sectional view of a stack structure inside a capacitor having variable capacitance according to another exemplary embodiment of the present invention. FIGS. 7A, 7B and 7C are plan views showing the structure of a metal layer inside the stack structure of the capacitor of FIG. 6. FIG. 8 is a cross-sectional view showing a capacitor adopting the stack structure of FIG. 6.

As shown in FIGS. 6 through 8, a stack structure 60 for a capacitor, according to another exemplary embodiment of the present invention, includes a first metal layer 611 formed on almost the entire surface of one layer, and other metal layers 62 and 63 formed on different levels from the first metal layer 611. The metal layer 62 includes a plurality of parts 621 to 624 that are separated on the same layer, and the metal layer 63 includes a plurality of parts 631 to 633 that are separated on the same layer.

The plurality of parts 621 to 624 and the plurality of parts 631 to 633 may be disposed so as to avoid completely overlapping parts on different levels, so that each of them can directly face the first metal layer 611.

The shape of each of the parts 621 to 624 and 631 to 633 may have a rectangular shape. A capacitance formed between the first metal layer 611 and each of the parts 621 to 624 may be determined according to the horizontal and vertical lengths L1 and L2 of each of the parts 621 to 624, and by a distance t8 between the first metal layer 611 and each of the parts 621 to 624. In the same way, a capacitance formed between the first metal layer 611 and each of the parts 631 to 633 may be determined according to the horizontal and vertical lengths L3 and L4 of each of the parts 631 to 633, and by a distance t9 between the first metal layer 611 and each of the parts 631 to 633.

In this embodiment, a switch part may be connected between one terminal of the capacitor and each of the parts 621-624 and 631-633 of the other metal layers 62 and 63.

FIG. 8 illustrates an example of an inverter-type switch configuration depicted in FIG. 4.

In the example depicted in FIG. 8, the inverters 651 to 654 maybe controlled such that one of the parts 621 and 622 of the metal layer 62 and one of the parts 631 and 632 of the metal layer 63 are selectively connected to one terminal of the capacitor.

For example, referring to FIG. 8, when a logic high control signal is input, the part 621 of the metal layer 62 becomes logic low due to the inverter 651, to thereby form a capacitance C61 with the first metal layer 611 connected to power voltage Vdd. Also, the part 631 of the metal layer 63 becomes logic high due to the inverter 652 to thereby have substantially no potential difference with the first metal layer 611, thus forming no capacitance.

Similarly, the part 632 of the metal layer 63 becomes logic low due to the inverter 653 to thereby form a capacitance C62 with the first metal layer 611 connected to the power voltage Vdd, and the part 622 of the metal layer 62 becomess logic high due to the inverter 654 to thereby have substantially no potential difference with the first metal layer 611, thus forming no capacitance.

The embodiment depicted in FIGS. 6 through 8 is associated with a capacitor having an MOM capacitor stack structure using a three metal layer process.

In this embodiment, the first metal layer 611 is connected to the power voltage Vdd, and each of the metal layers 62 and 63 is separated into a plurality of parts. That is, the metal layer on the same layer is formed as a plurality of separate parts, rather than a single conductor. That is, the metal layer 62 may include the parts 621 to 624, and the metal layer 63 may include the parts 631 to 633. One part of one metal layer is paired up with one part of another metal layer to thereby form a difference capacitance from another pair through switching.

As shown in FIG. 8, the part 621 of the metal layer 62 and the part 631 of the metal layer 63 may be connected to the outputs of the two-stage inverters 651 and 652, while the part 622 of the metal layer 62 and the part 632 of the metal layer 622 may be connected to the outputs of other two-stage inverters 653 and 654. These inverters operate in the same way as described with reference to FIG. 4.

In this embodiment, the dielectric thickness t8 between the first metal layer 611 and the metal layer 62 is different from the dielectric thickness t9 between the first metal layer 611 and the metal layer 63. Thus, the capacitance C61 between the first metal layer 611 and each of the parts 621 and 622 of the metal layer 62 is different from the capacitance C62 between the first metal layer 611 and each of the parts 631 and 632 of the metal layer 63.

Thus, by the above-described operation, each capacitance is activated/deactivated using a digital control signal, to thereby obtain a unit capacitance.

For example, in FIG. 8, when a logic high control signal is applied to the two-stage inverters 651 and 652, and 653 and 654, negative charges are induced to the part 621 of the metal layer 62 and an electric field is formed to thereby form a capacitance C61. Also, negative charges are induced to the part 632 of the metal layer 63 and an electric field is formed to thereby form a capacitance C62.

In contrast, when a logic low control signal is applied to the two-stage inverters 651 and 652, and 653 and 654, negative charges are induced to the part 622 of the metal layer 62 and an electric field is formed to thereby form a capacitance C61. Also, negative charges are induced to the part 631 of the metal layer 63 to thereby form a capacitance C62.

As for the embodiment of FIGS. 6 and 7, the metal layers are separated and disposed the left and right sides, thereby generating a capacitance variation ΔC when a control signal is transited. This maybe expressed by Equation 9 below:

$$Δ C = C 61 - C 62 = ɛ S ( \frac{1}{t 8} - \frac{1}{t 9} ) = ɛ S ( \frac{t 9 - t 8}{t 8 t 9} ) = ɛ S ( \frac{Δ t}{t 8 t 9} ) \qquad Equation 9$$

As shown in Equation 9 above, a capacitance variation, that is, a unit capacitance ΔC, may be created by using a thickness variation Δt of a dielectric body, and inverter relay switches in the stack structure having the MOM capacitor structure.

FIG. 9 is a circuit diagram showing one example of a DCO to which a capacitor having variable capacitance according to the present invention is applicable.

The DCO depicted in FIG. 9 includes an inductor L0 91, a capacitor-array bank 92 employing a capacitor having variable capacitance according to the present invention, and a cross-coupled pair 93.

An LC resonator including the inductor 91 and the capacitor array bank 92 generates a resonant frequency, and the cross-coupled pair 93 compensates for the loss of the LC resonator with a negative-resistance cross-coupled pair to thereby create and continue oscillation.

The capacitor array bank 92 includes a coarse-tuned bank 921 and a fine-tuned bank 922, and the above capacitor having variable capacitance according to the present invention is applied to the coarse-tuned bank 921 and the fine-tuned bank 922.

The frequency resolution of the DCO 90 depicted in FIG. 9 is determined by the capacitance resolution of the fine-tuned bank 922.

The LC resonator is configured by connecting both ends of the capacitor array bank 92 with the inductor 91, and the middle of the inductor 91 may be connected to the power voltage Vdd.

The fine-tuned bank 922 of the capacitor array bank 92 may include a plurality of unit capacitors C21 to C27 (e.g., seven unit capacitors) each having a unit capacitance resolution. As the switches respectively connected to the unit capacitors C21 to C27 are shorted (turned ON) by a digital control signal, the overall capacitance of the fine-tuned bank 922 increases in proportion to the number of unit capacitors.

The coarse-tuned bank 921 of the capacitor array bank 92 may include a basic capacitance C11 so as to be able to create a frequency resolution sufficient to cover a desired radio frequency (RF) bank. The coarse-tuned bank 921 may include capacitances C12 to C17 that is 2, 4, 8, 16, 32, 64 and 128 times greater than the base capacitance C11.

The cross-coupled pair 103 has a structure in which the drains and gates of two NMOS transistors are cross-coupled, and generate negative resistance to compensate for the loss of the LC resonator.

As set forth above, according to exemplary embodiments of the invention, a capacitance array bank employed for a DCO adopting an LC resonator may have an improved resolution of capacitance, that is, a unit capacitance variation of the capacitance array bank. Thus, the frequency resolution of the DCO adopting the LC resonator may be improved. This allows for a reduction in the use of digital circuit blocks for enhancing the frequency resolution of a digital PLL frequency synthesizer, thereby achieving a reduction in power consumption and chip area.

While the present invention has been shown and described in connection with the exemplary embodiments, it will be apparent to those skilled in the art that modifications and variations can be made without departing from the spirit and scope of the invention as defined by the appended claims.

What is claimed is:

1. A capacitor having variable capacitance, comprising:
a stack structure comprising a plurality of metal layers including a first metal layer, and a plurality of dielectric layers respectively interposed between the plurality of metal layers; and
a switch part comprising at least one switch having one side connected to at least one metal layer among the plurality of metal layers other than the first metal layer,
wherein the first metal layer and the other side of the switch serve as both terminals of the capacitor, and at least two capacitances are provided between both terminals of the capacitor upon controlling a short/open of the switch.

2. The capacitor of claim 1, wherein the dielectric layers are formed of an oxide.

3. The capacitor of claim 1, wherein the stack structure is formed by using a complementary metal oxide semiconductor (CMOS) process.

4. The capacitor of claim 1, wherein the stack structure comprises the first metal layer, a second metal layer facing the first metal layer with the dielectric layer therebetween, and a third metal layer facing the first metal layer with the dielectric layer therebetween, the second metal layer and the third metal layer each being spaced apart from the first metal layer at a different interval by the dielectric layer, and
the switch part comprises a first switch formed between the first metal layer and the second metal layer, and a second switch formed between the first metal layer and the third metal layer.

5. The capacitor of claim 4, wherein the first switch is an N-channel MOS transistor including a drain connected to one terminal of the capacitor and a source connected to the second metal layer,
the second switch is a P-channel MOS transistor including a source connected to the one terminal of the capacitor and a drain connected to the third metal layer, and
a common control signal is input to respective gates of the N-channel MOS transistor and the P-channel MOS transistor.

6. The capacitor of claim 1, wherein the stack structure comprises the first metal layer, a second metal layer facing the first metal layer with the dielectric layer therebetween, and a third metal layer facing the first metal layer with the dielectric layer therebetween, the second metal layer and the third metal layer each being spaced apart from the first metal layer at a different interval by the dielectric layer, and
the switch part comprises a first inverter having an input terminal to which a control signal is input, and an output terminal connected to the third metal layer, and a second inverter having an input terminal connected to the output terminal of the first inverter and an output terminal connected to the second metal layer.

7. The capacitor of claim 6, wherein the first metal layer is disposed between the second metal layer and the third metal layer, and the first to third metal layers have substantially the same surface area.

8. The capacitor of claim 1, wherein the plurality of metal layers each have a different surface area,
the first metal layer of the plurality of metal layers has the largest surface area, and
the first metal layer and each of the other metal layers are disposed to have a region in which the first metal layer and each of the other meta layers face each other through the dielectric layer.

9. The capacitor of claim 1, wherein the first metal layer of the stack structure is formed on almost the entire surface of one layer, and the other metal layers thereof each has a plurality of parts separated on the same layer,
the switch part is connected between one terminal of the capacitor and each part of the other metal layers, and
a capacitance is formed selectively between the first metal layer and the parts of the other metal layers upon controlling a short/open of the switch.

10. A digitally controlled oscillator comprising:
a capacitor unit comprising a variable capacitor;
an inductor connected in parallel to the capacitor part; and
a cross-coupled pair connected to the capacitor unit and the inductor and generating negative resistance,
the variable capacitor including:
a stack structure comprising a plurality of metal layers including a first metal layer, and a plurality of dielectric layers respectively interposed between the plurality of metal layers; and
a switch part comprising at least one switch having one side connected to at least one metal layer among the plurality of metal layers other than the first metal layer,
wherein the first metal layer and the other side of the switch serve as both terminals of the capacitor, and at least two capacitances are provided between both terminals of the capacitor upon controlling a short/open of the switch.
